(19) United States
(12) Patent Application Publication
(10) Pub. No.: US 2018/0180958 A1
(43) Pub. Date: Jun. 28, 2018

(54) DISPLAY APPARATUS AND METHOD FOR REPAIRING THE SAME

(71) Applicant: Shenzhen China Star Optoelectronics Technology Co., Ltd, Shenzhen, Guangdong (CN)

(72) Inventor: Xiaoyu HUANG, Shenzhen, Guangdong (CN)

(73) Assignee: Shenzhen China Star Optoelectronics Technology Co., Ltd., Shenzhen, Guangdong (CN)

(21) Appl. No.: 15/304,520

(22) PCT Filed: Sep. 21, 2016
(86) PCT No.: PCT/CN2016/099508

§ 371 Date: Oct. 15, 2016

(30) Foreign Application Priority Data
Jul. 20, 2016 (CN) 201610578744.0

(51) Int. Cl. G02F 1/1362; G02F 1/1368; H01L 21/66; H01L 27/12

(52) U.S. Cl. CPC G02F 1/136259; G02F 1/1368; G02F 2001/136263; H01L 22/22; H01L 27/124; G02F 1/136286

(57) ABSTRACT

The present disclosure provides a display apparatus and a method for repairing the display apparatus. The display apparatus includes a display region and a non-display region. The display apparatus further includes: a repairing line provided on periphery of the display region; and a TFT provided on a chip, wherein a gate electrode of the TFT is connected to a control line, a source electrode of the TFT is connected to the repairing line, and a drain electrode of the TFT is connected to a data line or a scan line.

### TECHNICAL FIELD

The present disclosure belongs to the field of manufacturing display apparatus, and particularly relates to a display apparatus and a method for repairing the same.

### BACKGROUND ART

A TFT-LCD (Thin Film Transistor Liquid Crystal Display) is currently one of the main products for flat panel display, and has become an important display platform in modern information technology (IT) and video solutions. A principle of driving the TFT-LCD is mainly as follows: a system main board connects an R/G/B compression signal, a control signal and power with a connector on a printed circuit board (PCB), and after being processed by a timing controller integrated circuit on the PCB, data is connected with a display region by a source chip on film S-COF and a gate chip on film G-COF through the PCB, so as to allow the LCD to obtain the required power and signals.

In practical usage, due to a processing defect, a defect of line might occur. The existing repairing method is shown in FIG. 1, wherein a gate chip on film 20 and a source chip on film 30 are provided respectively around a display region 100, and the gate chip on film is provided between a printed circuit board 10 and the display region 100. When an A point on an output line 5 is a disconnection point, a section from the A point to the ground side cannot be displayed, and is presented as a disconnecting line. In order to repair the disconnecting line, the juncture points B and C of a repair line 4 and the output line 5 are welded by laser. The data of section AB are transmitted through an original output line, and the data of section AC are transmitted through the repair line, so as to achieve repair of line eventually.

A Chinese patent application CN201110402001.5 discloses a method for repairing liquid crystal display apparatus, wherein when a source electrode line is disconnected, the disconnected source electrode line and a corresponding repairing signal line overlapping with the source electrode line are welded at an overlapping portion by laser; a signal voltage of the disconnected source electrode line are lead out through the repairing signal line to a repairing unit to perform signal repair; a controller controls on and off of a corresponding compensating voltage switch based on a wiring length of the repairing line, then inputs a corresponding compensating voltage V into the repairing unit; after being combined with the repaired signal voltage, the compensating voltage V is output to the repairing line as a repairing voltage. The other end of the disconnected source electrode line and the corresponding repairing line overlapping with the source electrode line are welded at the overlapping portion by laser, so that the repairing voltage is transferred to the other end of the corresponding disconnected source electrode line through the repairing line, hence finishing the repairing process of the source electrode line.

However, the above method for repairing a display apparatus in the prior art is relatively complex, which needs to perform laser welding process for twice, thus the repairing will be less efficient.

### SUMMARY

A purpose of the present disclosure is to overcome the above defect in the prior art and to provide a display apparatus which can save a laser welding process, simplify the procedure, and increase the repairing efficiency.

Another purpose of the present disclosure is to overcome the above defect in the prior art and to provide a method for reparing a display apparatus which can save a laser welding process, simplify the procedure and increase the repairing efficiency.

In accordance with an aspect of the present disclosure, there is provided a display apparatus including a display region and a non-display region. The display apparatus further includes a repairing line provided at periphery of the display region; and a TFT provided on a chip, wherein a gate electrode of the TFT is connected to a control line, a source electrode of the TFT is connected to the repairing line, and a drain electrode of the TFT is connected to a data line or a scan line.

In accordance with an exemplary embodiment of the present disclosure, the repairing line can include a first portion and a second portion insulating from and intersecting with the data line and/or scan line, the first portion can be close to the TFT, and the second portion can be away from the TFT.

In accordance with an exemplary embodiment of the present disclosure, the gate electrode of the TFT can be controlled by the control line to disconnect or connect the repairing line with the data line or the scan line.

In accordance with an exemplary embodiment of the present disclosure, the chip can be a source chip on film and/or a gate chip on film.

In accordance with an exemplary embodiment of the present disclosure, the source chip on film can be provided outside the display region, and can be provided between a printed circuit board and the display region, wherein a plurality of source chips on film can be provided along the outside of the display region at intervals.

In accordance with an exemplary embodiment of the present disclosure, the gate chip on film can be provided outside the display region, and can be provided at a position adjacent to the position where the source chip on film is provided, wherein a plurality of gate chips on film can be provided along the outside of the display region at intervals.

In accordance with another aspect of the present disclosure, there is provided a method for repairing a display apparatus, the method comprising: detecting whether a disconnected line exists in a display region; if a disconnected line is detected, allowing the control line to output a predetermined voltage to turn on the TFT so as to allow the repairing line to be connected with the data line or the scan line; and welding a portion where the repairing line intersects with and insulates from the data line and/or the scan line by laser.

In accordance with an exemplary embodiment of the present disclosure, the portion where the repairing line intersects with and insulates from the data line and/or the scan line can be a second portion of the repairing line.

### BRIEF DESCRIPTION OF THE DRAWINGS

FIGS. 1 and 2 show a method for repairing a display apparatus in the prior art; and

FIG. 3 shows a method for repairing a display apparatus in accordance with an exemplary embodiment of the present disclosure.

### DETAILED DESCRIPTION OF EXEMPLARY EMBODIMENTS

Here, the display apparatus and the repairing method of the display apparatus in accordance with the exemplary embodiment of the present disclosure will be described based on the exemplary embodiment, while the present disclosure is not limited to the following exemplary embodiment. On the contrary, the examples are only raised for explanation and interpretation, and to completely convey the protection scope of the claims to those skilled in the art.

The claims and description of the present disclosure may disclose steps carried out in sequence. However, said steps are not bound to be carried out in sequence. That is to say, regarding two steps carried out in sequence, they can be executed one by one in accordance with the described sequence, and can also be executed simultaneously according to the requirement in technique, or can be executed in an inverse sequence, also, there can be intermediate steps there-between.

In the prior art, due to a processing defect, a defect of line might occur to the display apparatus. However, regarding the above defect of line, the existing repairing method is to weld two overlapping points of a repairing line and an output line by laser in order to achieve line repair eventually. However, regarding the above repairing method, since the laser welding process is performed for twice, the repairing process is complex.

The present disclosure provides a display apparatus which can save a laser welding process, simplify the procedure, and increase the repairing efficiency, and a method for repairing the display apparatus.

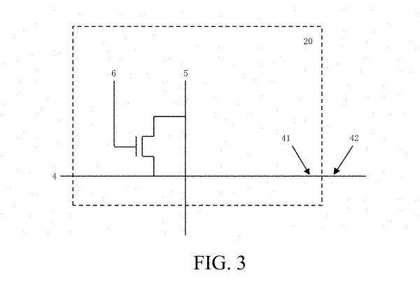

Hereinafter, the display apparatus and the method for repairing the same in accordance with inventive concept of the present disclosure will be described in detail with reference to FIG. 3.

In accordance with an aspect of the present disclosure, there is provided a display apparatus including a display region and a non-display region. The display region is arranged with a plurality of pixels which emit lights of three colors such as red, yellow and blue under the control of a control line. The non-display region is provided on periphery of the display region, and is arranged with metal wiring thereon.

In addition, the display apparatus further includes: a repairing line 4 provided to be surrounding the display region, wherein the repairing line 4 can include a portion 41 provided on a chip 20 and a portion 42 provided outside the chip 20; and a TFT provided within the chip 20, wherein a gate electrode of the TFT is connected to a control line 6, a source electrode of the TFT is connected to the repairing line 4, and a drain electrode of the TFT is connected to a data line or a scan line 5.

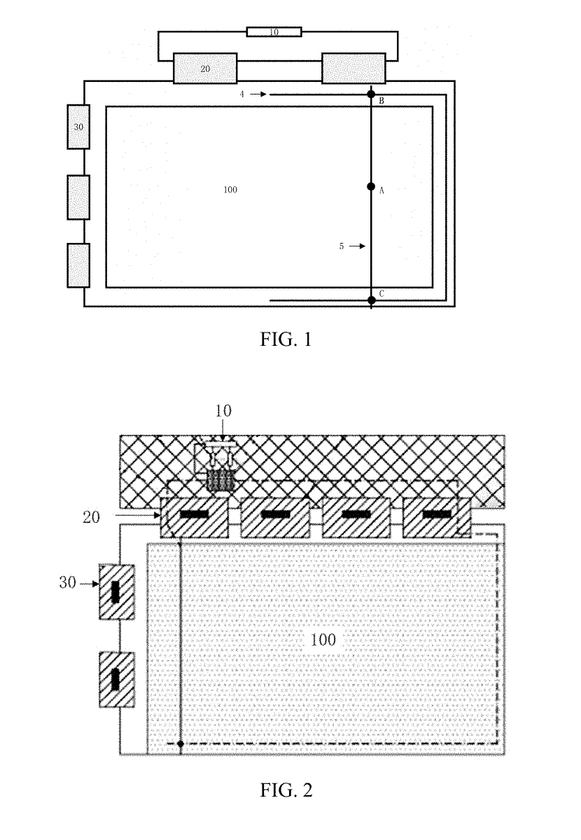

In accordance with an exemplary embodiment of the present disclosure, the repairing line 4 can include a first portion and a second portion insulating from and intersecting with the data line and/or scan line 5, wherein the first portion is close to the TFT, and the second portion is away from the TFT. For example, referring to the prior art shown in FIG. 1, the first portion can similarly correspond to a point B of the repairing line 4 in the prior art shown in FIG. 1, the point B intersecting with and insulating from the data line and/or the scan line 5, and the second portion can similarly correspond to a point C of the repairing line 4 in the prior art shown in FIG. 1, the point C intersecting with and insulating from the data line and/or the scan line 5. In accordance with an exemplary embodiment of the present disclosure, when a disconnection of scan line/data line 5 is detected, the TFT can be controlled to be turned on (for example, applying a gate control signal through a control line 6 to turn on the TFT) so as to allow the scan line/data line 5 to be connected with a repairing line 1, and to weld the second portion where the scan line/data line 5 insulates from and intersects with the repairing line 1 by laser.

In accordance with an exemplary embodiment of the present disclosure, the above chip can include a source chip on film and/or a gate chip on film. A plurality of source chips on film can be provided outside the display region, and can be provided between a printed circuit board and the display region. In this instance, the plurality of source chips on film can be provided along the outside of the display region at intervals.

In accordance with an exemplary embodiment of the present disclosure, the above chip can further include a gate chip on film. A plurality of gate chips on film can be provided outside the display region, and can be provided at a position adjacent to the position where the source chip on film is provided, wherein the plurality of gate chips on film can be provided along the outside of the display region at intervals.

In the prior art, as shown in FIG. 1, when an A point on an output line 5 is a disconnection point, a section from the A point to the ground side cannot be displayed, and is presented as a disconnecting line. In order to repair the disconnecting line, the juncture points B and C of the repair line 4 and the output line 5 are welded by laser, data of section AB is transmitted through an original output line, and data of section AC is transmitted through the repair line, so as to achieve repair of line eventually.

In contrast, in accordance with the display apparatus including the repairing line and the TFT of the exemplary embodiment of the present disclosure, the TFT is connected respectively to the repairing line 4 and the data line and/or the scan line 5. When repairing a defect of line in the display apparatus, a connection of the repairing line 4 with the data line and/or the scan line 5 close to a TFT side can be controlled through the TFT (for example, a connection of the repairing line 4 with the data line and/or the scan line 5 close to the point B shown in FIG. 1 can be controlled through the TFT), and thus a step of welding the point B shown in FIG. 1 by laser can be omitted.

In other words, in FIG. 1 of the prior art, a laser welding process is required to be performed on the point B and the point C, respectively. However, in accordance with an embodiment of the present disclosure, the laser welding process is only performed on the point C, while a connection of the repairing line 4 with the data line and/or the scan line 5 close to the point B is achieved through turning on the TFT (i.e., there is no need to weld the point B by laser), hence omitting the step of welding the point B by laser.

In summary, in accordance with an exemplary embodiment of the present disclosure, the TFT connecting the repairing line with the scan line/data line can be provided on, for example, a source chip on film, wherein the gate electrode of the TFT is controlled by the control line 6, and when a disconnection of scan line/data line is detected, a control signal can be applied through the control line 6 (e.g., applying a control voltage of 3.3V through the control line 6) to turn on the TFT, so as to allow the repairing line 4 to be connected with the scan line/data line 5. In addition, the portion where the scan line/data line 5 intersects with and insulates from the repairing line 4 (e.g., the second portion of the repairing line) can be welded by laser, hence finishing the repairing process of the scan line and/or data line 5 via the repairing line.

It should be understood that, although the present description is described according to the embodiments, each embodiment may not only include one independent technical solution, while such expression method in the description is only used for clarity. Those skilled in the art should deem the description as an entirety, and the technical solutions of the respective embodiments can also be combined properly to form other embodiments which can be understood by those skilled in the art.

The above series of detailed explanations are only the specific explanations with respect to the practicable embodiments of the present disclosure, which are not used to limit the protection scope of the present disclosure, and all equivalent embodiments or changes not deviating from the spirit of the art of the present disclosure shall fall within the protection scope of the present disclosure.

1. A display apparatus comprising a display region and a non-display region, the display apparatus further comprising:
a repairing line provided on periphery of the display region; and
a TFT provided on a chip,
wherein a gate electrode of the TFT is connected to a control line, a source electrode of the TFT is connected to the repairing line, and a drain electrode of the TFT is connected to a data line or a scan line.

2. The display apparatus of claim 1, wherein the repairing line comprises a first portion and a second portion insulating from and intersecting with the data line and/or scan line, the first portion is close to the TFT, and the second portion is away from the TFT.

3. The display apparatus of claim 1, wherein the gate electrode of the TFT is controlled by the control line to disconnect or connect the repairing line with the data line or the scan line.

4. The display apparatus of claim 1, wherein the chip is a source chip on film and/or a gate chip on film.

5. The display apparatus of claim 4, wherein the source chip on film is provided outside the display region, and is provided between a printed circuit board and the display region, and wherein a plurality of source chips on film is provided along the outside of the display region at intervals.

6. The display apparatus of claim 5, wherein the source chip on film is provided outside the display region, and is provided at a position adjacent to the position where the source chip on film is provided, and wherein a plurality of gate chips on film is provided along the outside of the display region at intervals.

7. A method for repairing the display apparatus of claim 1, the method comprising:
detecting whether a disconnected line exists in the display region;
if a disconnected line is detected, allowing the control line to output a predetermined voltage to turn on the TFT, so as to allow the repairing line to be connected with the data line or the scan line; and
welding a portion where the repairing line intersects with and insulates from the data line and/or the scan line by laser.

8. The method for repairing the display apparatus of claim 7, wherein the portion where the repairing line intersects with and insulates from the data line and/or the scan line is a second portion of the repairing line.
